(19) United States
(12) Patent Application Publication
(10) Pub. No.: US 2005/0156586 A1
(43) Pub. Date: Jul. 21, 2005

(54) Combination test method and test device

(75) Inventor: Takamasa Kanbayashi, Kanagawa (JP)

Correspondence Address: FOLEY AND LARDNER;SUITE 500, 3000 K STREET NW, WASHINGTON, DC, 20007, US

(73) Assignee: NEC Electronics Corporation

(21) Appl. No.: 11/034,837

(22) Filed: Jan. 14, 2005

(30) Foreign Application Priority Data
Jan. 19, 2004 (JP) 2004-010681
Nov. 19, 2004 (JP) 2004-335727

(51) Int. Cl. G01R 23/12

(52) U.S. Cl. 324/76.53

(57) ABSTRACT

In the combination test method according to the present invention, by applying jitter to a first clock signal having a lower frequency than a second clock signal having a second frequency, jitter is superimposed onto data of a second format output by a transmission device at a data rate corresponding to the second frequency. Conventionally, in order to apply jitter to data having a high data rate, it has been necessary to use a highly expensive jitter generating device that is compatible with a high-speed signal, but in the present invention, since the signal to which the jitter is applied is a first clock signal of low speed, then a highly expensive jitter generating device is not required. Therefore, it is possible to easily test whether or not a receiving device inputting data of a second format can accurately reproduce data of a first format.

### BACKGROUND OF THE INVENTION

1. Field of the Invention

The present invention relates to a combination test method and test device, and more particularly, to a combination test method and test device in which a signal transmitted by a transmission device which converts data of a first format to data of a second format is input to a receiving device which reproduces data of the first format from data of the second format, and it is determined whether or not the signal transmitted by the transmission device matches the signal reproduced by the receiving device.

2. Description of Related Art

In recent years, data transfer speeds in semiconductor devices have increased and data transfer at very high data rates of several Gbps (gigabits per second), for example, have been achieved. Generally, in the case of parallel transmission, it is difficult to adjust the skew between signals, and therefore the tendency is for serial transmission to be used for high-speed data transfer. FIG. 7 shows a case where parallel data is transferred between two semiconductor devices by means of serial transfer. The semiconductor device A (201) and the semiconductor device B (202) respectively have a transmission and receiving device (SerDes: Serializer/Deserializer) 204 and 205, at their interface with the transmission path 203.

The transmission and receiving devices 204 and 205 each comprise a serializer 210 and a deserializer 220. The serializer 210, for example, converts 8-bit parallel data input at a data rate corresponding to 312.5 MHz, to serial data at a data rate corresponding to 2.5 GHz, and it then outputs this serial data to the transmission path 203. The deserializer 220 inputs serial data from the transmission path 203, converts that serial data by means of an inverse method to that of the serializer 210, and reproduces (8-bit) parallel data at a data rate corresponding to 312.5 MHz.

FIG. 8 shows a case where the transmission and receiving device 204 (or 205) is subjected to a loop-back test. The serial data output by the serializer 210 is high-speed data at a data rate of several Gbps, and hence it is difficult to evaluate the quality of the data directly by means of the serial data. Therefore, generally, in order to evaluate the functions of a transmission and receiving device, a method is adopted wherein a serializer 210 and deserializer 220 are combined and, as shown in FIG. 8, the serial data output by the serializer 210 is input to the deserializer 220 and it is tested whether or not the deserializer 220 is able to reproduce the data accurately.

The serializer 210 comprises a PLL (Phase Lock Loop) circuit 211, and a reference clock signal CLK is input to this PLL circuit 211. The PLL circuit 211 multiplies the 78.125-MHz reference clock signal CLK by 32, thereby generating a 2.5-GHz multiplied clock signal. The pattern generating section 231 generates a 312.5-Mbps PRBS (Pseudo Random Bit Sequence) and inputs this PRBS signal to the serializer 210 as a test pattern. The serializer 210 converts the input test pattern to serial data, and outputs this serial data in synchronization with the 2.5-GHz multiplied clock signal generated by the PLL circuit 211.

The deserializer 220 reproduces the clock signal from the input serial data (=Output of the serializer 210), by means of a CDR (clock and data recovery) section 221, whilst also reproducing the parallel data (test pattern). A pattern comparing section 232 compares the test pattern input to the serializer 210 by a pattern generating section 231 with the test pattern reproduced by the deserializer 220, returns a “pass” determination if the two test patterns are matching, and returns a “fail” determination if the test patterns are not matching. The test results are input to a measurement device, and the measurement device indicates the test result, “pass” or “fail”.

The serializer 210 internally generates unavoidable jitter of approximately 0.15 UI (Unit Interval: ratio of jitter with respect to data cycle) (60 ps), with respect to the 2.5-Gbps serial data (cycle: 400 ps). Therefore, in the aforementioned loop-back test, the deserializer 220 tests whether or not the parallel data can be reproduced accurately, in a state where jitter of 0.15 UI is superimposed on the serial data. However, in an actual transmission path 203 (FIG. 7), jitter of approximately 0.4 UI to 0.6 UI may be superimposed on the serial data. Consequently, a test whereby the deserializer 220 simply tests whether or not parallel data can be reproduced accurately from serial data having jitter of 0.15 UI is not sufficient as a product test, and there have been demands for loop-back testing wherein the deserializer 220 performs testing in a state where jitter of approximately 0.4 UI to 0.6 UI is superimposed on the serial data.

In order to test whether or not parallel data can be reproduced accurately from serial data that is superimposed with jitter of approximately 0.4 UI to 0.6 UI, it is necessary to apply jitter of this range to the serial data input to the deserializer 220. A conventional method for applying jitter to a signal output by a transmitter is disclosed in Japanese Unexamined Patent Application Publication No. 2002-368827. In this method, a jitter applying section is provided in a signal line corresponding to that from the serializer 210 to the deserializer 220 in FIG. 8, and jitter is applied directly to the serial data.

Furthermore, a further method for generating a signal that is superimposed with jitter is disclosed in Japanese Unexamined Patent Application Publication No. 10-224213. In this method, a jitter signal is applied to the input of a voltage controlled oscillator forming a PLL circuit, and a periodic signal that is superimposed with a prescribed amount of jitter is generated.

However, in the loop-back test illustrated in FIG. 8, if jitter is to be applied directly to the serial data, similarly to Japanese Unexamined Patent Application Publication No. 2002-368827, then since the serial data is transferred at an extremely fast speed, a highly expensive jitter generating device will be required. Moreover, the method disclosed in the Japanese Unexamined Patent Application Publication No. 10-224213 involves applying jitter to a periodic signal, and does not provide a method for applying jitter to serial data that changes constantly. Therefore, a jitter generating device of this kind cannot be applied directly to a loop-back test.

### SUMMARY OF THE INVENTION

In the combination test method and test device according to the present invention, by applying jitter to a first clock signal having a lower frequency than a second clock signal having a second frequency, jitter is superimposed onto data of a second format output by a transmission device at a data rate corresponding to the second frequency. Conventionally, in order to apply jitter to data having a high data rate, it has been necessary to use a highly expensive jitter generating device that is compatible with a high-speed signal, but in the present invention, since the signal to which the jitter is applied is a first clock signal of low speed, then a highly expensive jitter generating device is not required. Therefore, it is possible to easily test whether or not a receiving device inputting data of a second format can accurately reproduce data of a first format.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a loop-back test device according to one embodiment of the present invention;

FIG. 2 is a circuit diagram showing the structure of a jitter generating macro 101;

FIG. 3 is a diagram showing the signal waveforms of the terminals T2 and B2;

FIG. 4 is another diagram showing the signal waveforms of the terminals T3 and B3;

FIGS. 5A and 5B are time charts respectively showing the operation of parts of serializer 105;

FIG. 6 is a time chart showing the operation of parts of deserializer 106;

FIG. 7 is a block diagram showing the case where parallel data is transferred serially between two semiconductor devices; and

FIG. 8 is a block diagram showing a loop-back test of transmission and receiving device 204 and 205.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

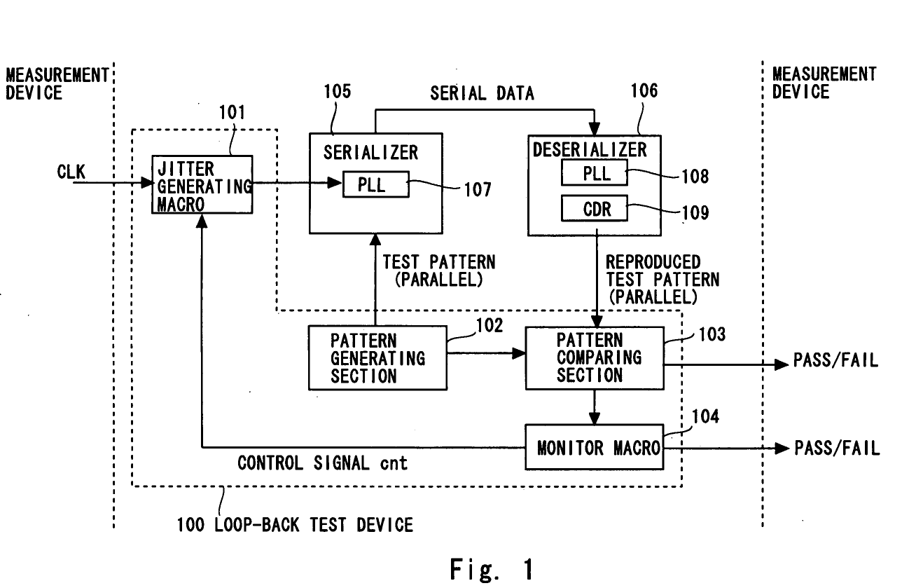

FIG. 1 shows a loop-back test device according to one embodiment of the present invention. This loop-back test device 100 comprises a jitter generating macro 101, a pattern generating section 102, a pattern comparing section 103, and a monitor macro 104. The loop-back test device 100 is incorporated into the same semiconductor device as that of a serializer 105 forming a transmission device and a deserializer 106 forming a receiving device. The loop-back test device 100 tests the functions of the serializer 105 and the deserializer 106 by means of a loop-back test which combines both the serializer 105 and the deserializer 106.

The pattern generating section 102 generates a PRBS signal, and this PRBS signal is input to the serializer 105 as a test pattern for the parallel data. The jitter generating macro 101 inputs a reference clock signal CLK (first clock signal) of 78.125 MHz, for example, from a measurement device, and applies a prescribed amount of jitter, for example, jitter of 100 ps, to that reference clock signal CLK. The jitter generating macro 101 is able to apply a prescribed amount of jitter in a plurality of cycles (frequencies). The cycle at which the jitter generating macro 101 applies the prescribed amount of jitter is controlled by means of a control signal cnt that is input form the monitor macro 104.

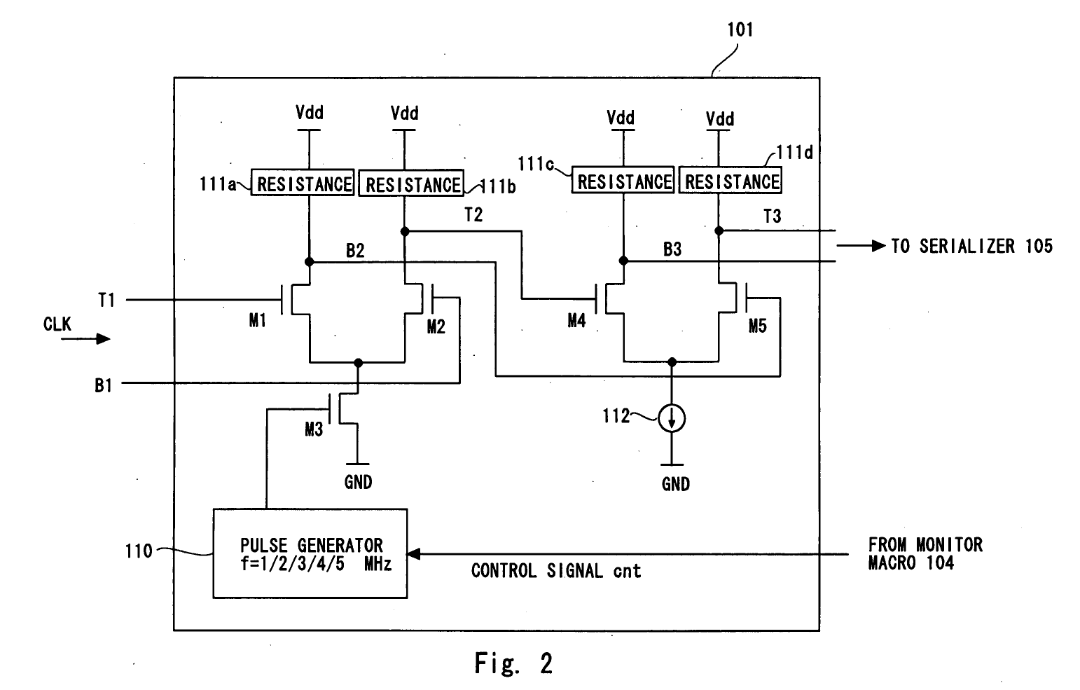

FIG. 2 shows an example of the structure of the jitter generating macro 101. This jitter generating macro 101 comprises a pulse generator 110, a differential pair of transistors M1 and M2, a serial transistor M3, a differential pair of transistors M4 and M5, a load, and a constant-current power source 112. In the structural example shown in FIG. 2, resistances 111a to 111d are used as loads. During a combination test, the pulse generator 110 outputs a pulse signal having a frequency of either 1 MHz, 2 MHz, 3 MHz, 4 MHz or 5 MHz, for example, on the basis of the control signal cnt input from the monitor macro 104, and during normal operation, it outputs a signal having a constant level. The pulse signal output by the pulse generator 110 is set in such a manner that it does not reach to or below a level at which the transistor M3 switches off.

The gates of the differential pair of transistors M1 and M2 are connected respectively to the terminals T1 and B1 which input a pair of complementary clock signals. The gate of the serial transistor M3 is connected to the output of the pulse generator 110. During a combination test, the current flowing in the serial transistor M3 changes in accordance with the characteristics of the transistor M3 and the level of the pulse signal input to the gate of the serial transistor M3 from the pulse generator 110.

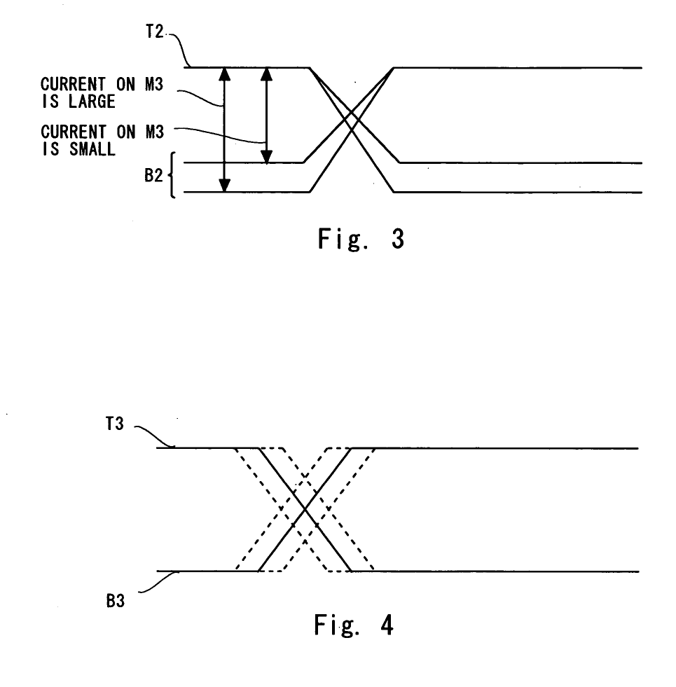

Since the current flowing in the serial transistor M3 varies, then the output amplitudes at the terminals B2 and T2, which form the outputs for the pair of complementary clock signals, change as illustrated in FIG. 3, on the basis of the characteristics of the transistors M1 and M2. The gates of the differential pair of transistors M4 and M5 are connected respectively to the terminals B2 and T2, which input the pair of complementary clock signals. When signals showing amplitude variation such as that illustrated in FIG. 3 are input to the gates of the differential pair of transistors M4 and M5, then due to delay fluctuation caused by the characteristics of the transistors M4 and M5 and rounding of the waveforms, the pair of complementary clock signals output from the output terminals B3 and T3 form a signal which contains the jitter illustrated in FIG. 4. The observed jitter width is indicated by the dashed line waveform in FIG. 4. According to this structural example of the jitter generating macro 101, a prescribed amount of jitter is applied to the reference clock signal CLK.

The serializer 105 comprises a PLL circuit 107 and operates on the basis of the reference clock signal CLK input via the jitter generating macro 101. The serializer 105 converts a test pattern input from the pattern generating section 102 at a data rate of 312.5-Mbps, for example, from parallel to serial data by means of a prescribed method, and then outputs the test pattern that has been converted to serial data, as serial data having a data rate of 2.5 Gbps, for example.

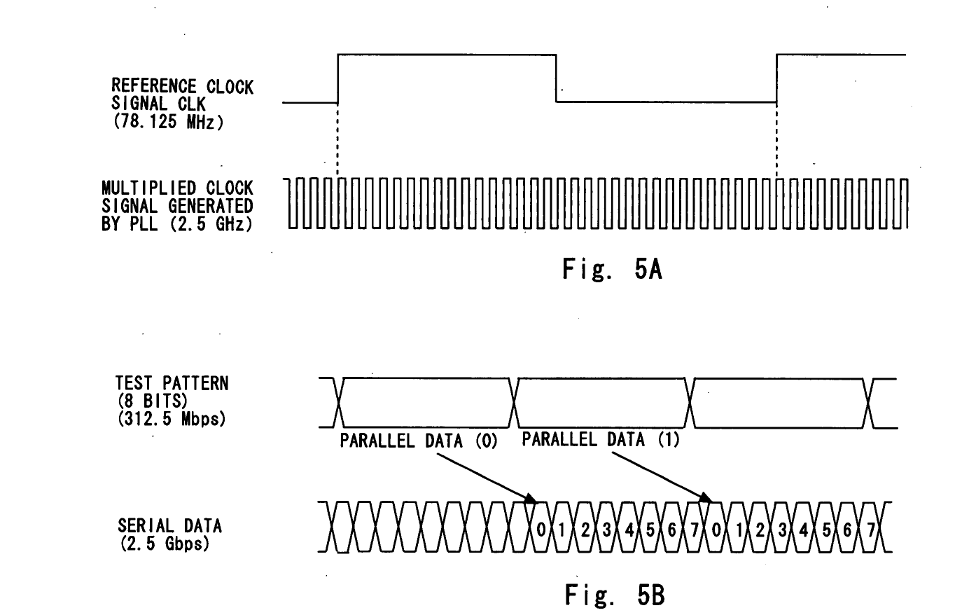

FIG. 5A and FIG. 5B show the operations of the respective parts of the serializer 105 in the form of a timing chart. As indicated in FIG. 5A, the PLL circuit 107 inputs the reference clock signal CLK to which jitter has been applied by the jitter generating macro 101, and it multiplies this reference clock signal CLK by 32, for example, in order to generate a 2.5-GHz multiplied clock signal (second clock signal). The prescribed amount of jitter applied to the reference clock signal CLK is superimposed on this multiplied clock signal. As shown in FIG. 5B, the serializer 105 converts an 8-bit test pattern input from the pattern generating section 102 into serial data and outputs this serial data in synchronization with the multiplied clock signal generated by the PLL circuit 107.

If the prescribed amount of jitter applied to the reference clock signal CLK by the jitter generating macro 101 is 100 ps, then the PLL circuit 107 which inputs the reference clock signal CLK via the jitter generating macro 101 will generate a multiplied clock signal that is superimposed with jitter of 100 ps. Unavoidable jitter of approximately 60 ps is generated within the serializer 105, and hence the serializer 105 outputs serial data having a combined jitter of 160 ps (0.4 UI), being the sum of the jitter (60 ps) generated inside the serializer 105 and the jitter (100 ps) applied to the reference clock signal CLK by the jitter generating macro 101. The amount of jitter applied to the reference clock signal CLK by the jitter generating macro 101 is selected in such a manner that the amount of jitter superimposed on the serial data falls in the range of 0.4 UI to 0.6 UI, taking account of the normal operating conditions of the serializer 105 and the deserializer 106.

The deserializer 106 comprises a PLL circuit 108 and a CDR section 109. The deserializer 106 inputs the test pattern that has been converted to serial data, at a data rate of 2.5 Gbps. The deserializer 106 converts the serial data thus input, from serial to parallel data, by means of an inverse method to that of the parallel to serial conversion in the serializer 105, and it outputs this test pattern which has been converted back to parallel data, at a data rate of 312.5-Mbps.

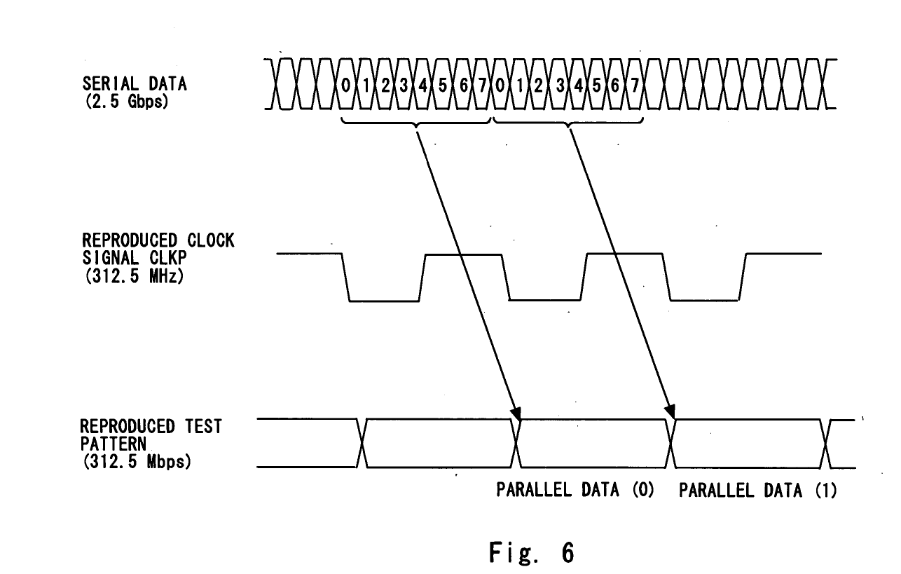

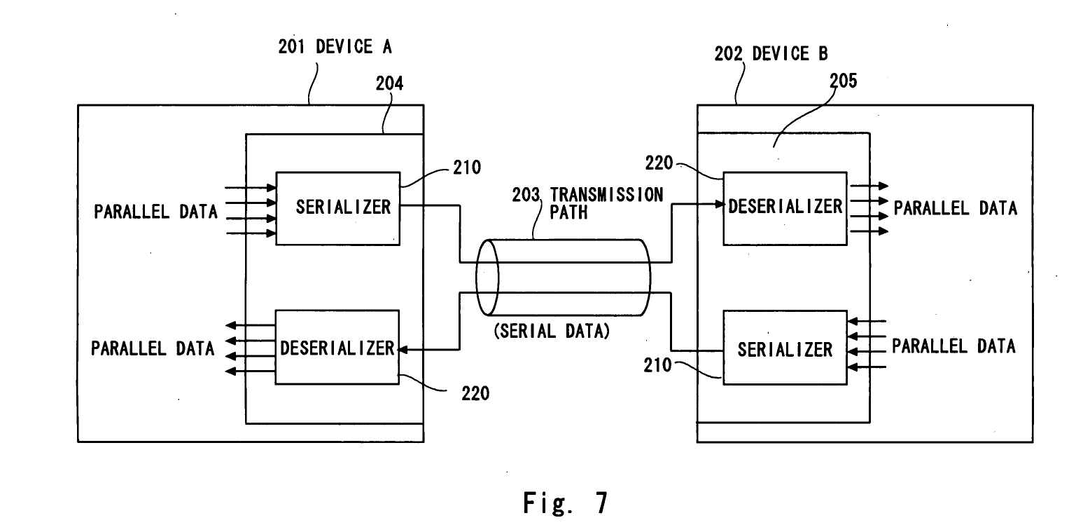

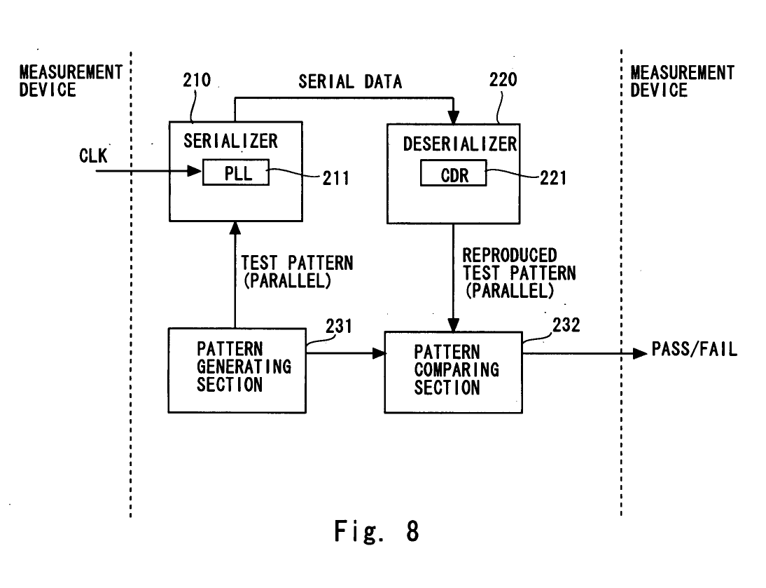

FIG. 6 shows the operations of the various parts of the deserializer 106 in the form of a timing chart. The deserializer 106 inputs the serial data superimposed with jitter of 160 ps, in synchronization with the clock signal generated by the PLL circuit 108. The CDR section 109 reproduces the clock signal CLKP from the input serial data (=Output of the serializer 105). Furthermore, the deserializer 106 converts the input serial data from serial to parallel data by means of an inverse method to that of the parallel to serial conversion performed by the serializer 105, and it outputs the test pattern of parallel data obtained by this conversion step.

The test pattern reproduced by the serial to parallel conversion in the deserializer 106 is input to the pattern comparing section 103. The pattern comparing section 103 compares the test pattern reproduced by the deserializer 106 with the test pattern input to the serializer 105, in other words, the test pattern input from the pattern generating section 102, and determines whether or not a bit error has occurred by determining whether or not the two patterns are matching. The pattern comparing section 103 outputs the test result “pass” if no bit error has occurred, and it outputs the test result “fail” if a bit error has occurred.

The monitor macro 104 sends the control signal cnt to the jitter generating macro 101, thereby controlling the frequency at which jitter of the prescribed amount is superimposed onto the serial data. The monitor macro 104 associates the cycle at which jitter is applied to the reference clock signal CLK with the test result (Pass or Fail) obtained when jitter is applied at that cycle, and it outputs this associated information to the measurement device.

In the loop-back test device 100, the cycle at which jitter is applied to the reference clock signal CLK is increased gradually, for example, from 1 MHz, 2 MHz, and so on, by means of the control signal sent out by the monitor macro 104, and for each cycle of jitter, the jitter tolerance of the deserializer 106 is evaluated by testing whether or not the deserializer 106 is able to reproduce the test pattern accurately.

In the present embodiment, a reference clock signal CLK to which a prescribed amount of jitter has been applied is input to the PLL circuit 107, and therefore jitter of a prescribed amount, which exceeds the unavoidable jitter generated inside the serializer 105, is superimposed on the serial data output by the serializer 105. In general, when applying jitter to a high-speed signal having a high data rate, it is necessary to employ highly expensive measurement equipment and jitter generating equipment that is compatible with the high-speed signal. The present embodiment adopts a structure wherein jitter is applied to a reference clock signal CLK having a relatively low speed in comparison with the serial data, such as 78.125 MHz, for instance, and therefore, a loop-back test involving the serializer 105 and the deserializer 106 can be performed in a state where a prescribed amount of jitter is superimposed on the serial data, without requiring measurement equipment and jitter generating equipment that is compatible with high-speed signals. Furthermore, since the loop-back test device 100 is incorporated into a semiconductor device, such as an LSI, or the like, then a further beneficial effect is obtained in that an existing measurement device, LSI tester, or the like, can be used and hence special measurement devices or LSI testers are not required.

Here, the frequency band 1 MHz to 5 MHz of the jitter superimposed on the serial data is a frequency band where tracking is difficult due to the tracking behavior of the CDR section 109 in the deserializer 106, and it is also a frequency region which is important in terms of evaluating the jitter tolerance of the deserializer 106. Conventionally, in order to evaluate the jitter tolerance of a deserializer 106 with respect to jitter in this frequency band, a high-speed pattern generator is required to generate serial data superimposed with jitter at a cycle of 1 MHz to 5 MHz, but there has been a problem in that a pattern generator of this kind is highly expensive.

In the present embodiment, the monitor macro 104 controls the cycle at which jitter is applied to the reference clock signal CLK, by means of the control signal cnt that it sends out, and for each cycle at which jitter is applied, a test is performed to establish whether or not the test pattern can be reproduced accurately by the deserializer 106. In the present embodiment, since jitter is superimposed on the serial data by applying jitter to the reference clock signal CLK, it is possible to easily evaluate the jitter tolerance of the deserializer 106 with respect to jitter in the frequency band of 1 MHz to 5 MHz. Therefore, when demonstrating the jitter tolerance of the deserializer 106 to customers, for example, it is not necessary to prepare a highly expensive pattern generator, or the like.

The present embodiment was described in relation to an example where the serializer 105 and the deserializer 106 are mounted on the same semiconductor device and the combination test is constituted as a loop-back test, but the combination test according to the present invention does not have to be constituted in the form of a loop-back test, and it may also be implemented by combining a serializer 105 mounted on one semiconductor device with a deserializer 106 mounted on a different semiconductor device.

It is apparent that the present invention is not limited to the above embodiment and it may be modified and changed without departing from the scope and spirit of the invention.

1. A test method, in which a combination test is performed with respect to a transmission device comprising a PLL circuit for receiving a first clock signal having a first frequency and generating a second clock signal having a second frequency that is higher than the first frequency, and a data converting section for converting data of a first format into data of a second format and synchronizing this data of the second format with the second clock signal and outputting the same, and a receiving device having a data reproducing section for receiving data of the second format and reproducing data of the first format from the received data of the second format, comprising the steps of:
applying jitter of a prescribed amount to the first clock signal and inputting the resulting first clock signal to the PLL circuit; and
determining whether or not the data of the first format input to the transmission device matches the data of the first format reproduced by the receiving device.

2. The combination test method according to claim 1, wherein the frequency at which the jitter of a prescribed amount is applied can be selected from a plurality of frequencies.

3. The combination test method according to claim 1, wherein the data of a first format is parallel data and the data of a second format is serial data.

4. The combination test method according to claim 1, wherein the jitter of a prescribed amount is selected in such a manner that the amount of jitter in the second data that is output by the transmission device, is equal to or greater than 0.4 UI and equal to or less than 0.6 UI.

5. The combination test method according to claim 1, wherein the combination test is a loop-back test.

6. A test device, in which a combination test is performed with respect to a transmission device comprising a PLL circuit for receiving a first clock signal having a first frequency and generating a second clock signal having a second frequency that is higher than the first frequency, and a data converting section for converting data of a first format into data of a second format and synchronizing this data of the second format with the second clock signal and outputting the same, and a receiving device having a data reproducing section for receiving data of the second format and reproducing data of the first format from the received data of the second format; comprising:
jitter applying section applying jitter of a prescribed amount to the first clock signal and inputting the first clock signal to which the jitter of the prescribed amount has been applied, to the PLL circuit; and
determining section determining whether or not the data of the first format input to the transmission device matches the data of the first format reproduced by the receiving device.

7. The combination test device according to claim 6, further comprising a pattern generator for generating the data of a first format in the form of a test pattern.

8. The combination test device according to claim 6, wherein the jitter applying section selects one frequency from the plurality of frequencies and applies jitter of the prescribed amount at the selected frequency.

9. The combination test device according to claim 8, wherein the jitter applying section comprises: a differential pair of transistors, in which the first clock signal and a clock signal that is complementary to the first clock signal are input respectively to the gates of the transistors; and a serial transistor, connected in series to the differential pair of transistors, in which a pulse sequence set to have a variable frequency is input to the gate of the transistor.

10. The combination test device according to claim 8, further comprising: a monitor macro for specifying the frequency selected by the jitter applying section, and mutually associating and outputting the specified frequency and the result determined by the determining section.

11. The combination test device according to claim 6, wherein the combination test is a loop-back test.

12. A combination test device comprising:
a serializer for converting a test pattern in a parallel format into a serial format, on the basis of a clock signal;
a deserializer for converting a test pattern in a serial format output by the serializer, to a parallel format; and
a comparing circuit for comparing the test pattern input to the serializer with a test pattern output from the deserializer;
wherein jitter is applied to the clock signal supplied to the serializer.

13. A combination test method comprising the steps of:
applying jitter to a clock signal;
converting a test pattern of a parallel format into serial data, on the basis of a clock signal to which jitter has been applied;
converting serial data into parallel data; and
comparing the converted parallel data with the test pattern.
